(19) United States
(12) Patent Application Publication
(10) Pub. No.: US 2021/0384015 A1
(43) Pub. Date: Dec. 9, 2021

(54) PLASMA CLEANING METHODS FOR PROCESSING CHAMBERS

(71) Applicant: Applied Materials, Inc., Santa Clara, CA (US)

(72) Inventors: Huiyuan WANG, Santa Clara, CA (US); Rick KUSTRA, San Jose, CA (US); Kaushik ALAYAVALLI, Sunnyvale, CA (US); Eswaranand VENKATASUBRAMANIAN, Santa Clara, CA (US); Jay D. PINSON, II, San Jose, CA (US); Abhijit B. MALLICK, Fremont, CA (US)

(21) Appl. No.: 16/896,575

(22) Filed: Jun. 9, 2020

(51) Int. Cl. H01J 37/32; B08B 5/00; B08B 9/08

(52) U.S. Cl. CPC H01J 37/32862; B08B 5/00; B08B 2209/08; H01J 2237/335; B08B 9/08

(57) ABSTRACT

Embodiments of the present disclosure generally relate to clean methods for processing chambers, and more specifically relate to plasma clean methods for removing carbon films from surfaces within the processing chamber. A method for cleaning includes introducing a cleaning gas into a processing region within a processing chamber, where interior surfaces of the processing chamber have a coating containing amorphous carbon. The cleaning gas contains oxygen gas and a noble gas. The method also includes generating an ion coupled plasma (ICP) from the cleaning gas within an upper portion of the processing region and generating a bias across a substrate support in a lower portion of the processing region. The method further includes exposing the amorphous carbon to atomic oxygen ions produced from the oxygen gas and the ICP and removing the amorphous carbon from the interior surfaces with the atomic oxygen ions during a cleaning process.

### BACKGROUND

### Field

Embodiments of the present disclosure generally relate to methods and apparatuses utilized in the manufacture of electronic devices, and in particular to methods for cleaning processing chambers.

### Description of the Related Art

Plasma-enhanced chemical vapor deposition (PE-CVD) processes are employed to deposit films on substrates, such as semiconductor wafers. A PE-CVD process is conducted by introducing one or more gases into a process volume of a process chamber that contains a substrate. The one or more gases mix in a diffuser situated near the top of the chamber and are injected into a process volume through a plurality of holes or nozzles of the diffuser. During a PE-CVD process, the mixture of the one or more gases in the process volume are energized (e.g., excited) to generate a plasma by applying radio frequency (RF) energy to the chamber from an RF source coupled to the chamber. An electric filed is generated in the process volume such that atoms of a mixture of the one or more gases present in the process volume are ionized. The ionized atoms accelerated to the substrate support in PE-CVD facilitate deposition of a film on the substrate.

In addition to the desired material being deposited on the substrate, the material is incidentally deposited on the various exposed interior surfaces within the PE-CVD chamber or other types of processing chambers. For example, the material may be deposited on exposed surfaces of the substrate support, the showerhead, the sidewalls and/or the bottom of the processing chamber, as well as any other exposed surfaces within the processing chamber. Many types of materials are difficult to remove from the interior surfaces of the processing chamber. One group of materials that is difficult to remove from interior surfaces include carbon and carbon-based inorganic compounds and materials, for example, amorphous carbon. Such carbon-based inorganic compounds and materials may be so adhered to the interior surfaces of the processing chamber that the removal process may be too slow to be practical or may damage the underlying surfaces.

Thus, what is needed is a method for cleaning or otherwise removing coatings and other contaminants from interior surfaces of processing chambers.

### SUMMARY

Embodiments of the present disclosure generally relate to clean methods for processing chambers, and more specifically relate to plasma clean methods for removing carbon (e.g., amorphous carbon, diamond-like carbon (DLC), or other carbon films) from surfaces within the processing chamber. In one or more embodiments, a method for cleaning a processing chamber includes introducing a cleaning gas into a processing region within a processing chamber, where interior surfaces of the processing chamber have a coating containing amorphous carbon. The cleaning gas contains about 75 mole percent (mol %) to about 99 mol % of oxygen gas (O₂) and about 1 mol % to about 20 mol % of one or more noble gasses (e.g., argon). The method also includes generating an ion coupled plasma (ICP) from the cleaning gas within an upper portion of the processing region and generating a bias across a substrate support in a lower portion of the processing region. The method further includes exposing the amorphous carbon to atomic oxygen ions produced from the oxygen gas and the ion coupled plasma and removing the amorphous carbon from the interior surfaces by reacting the amorphous carbon with the atomic oxygen ions during a cleaning process.

In some embodiments, a method for cleaning a processing chamber includes introducing a cleaning gas into a processing region within a processing chamber, where interior surfaces of the processing chamber have a coating containing amorphous carbon and the cleaning gas contains oxygen gas and one or more noble gases. The cleaning gas is introduced into the processing chamber by flowing the oxygen gas at a flow rate of about 200 standard cubic centimeter per minute (sccm) to about 3,000 sccm and the noble gas at a flow rate of about 20 sccm to about 300 sccm. The method also includes generating an ICP from the cleaning gas within an upper portion of the processing region and generating a bias across a substrate support in a lower portion of the processing region. The method further includes exposing the amorphous carbon to atomic oxygen ions produced from the oxygen gas and the ion coupled plasma and removing the amorphous carbon from the interior surfaces by reacting the amorphous carbon with the atomic oxygen ions during a cleaning process.

In other embodiments, a method for cleaning a processing chamber includes introducing a cleaning gas into a processing region within a processing chamber, where interior surfaces of the processing chamber have a coating containing amorphous carbon. The cleaning gas contains about 75 mol % to about 99 mol % of oxygen gas and about 1 mol % to about 20 mol % of argon. The method also includes generating an ICP from the cleaning gas within an upper portion of the processing region, where the ion coupled plasma is generated from a power source having a power of about 3 kW to about 5 kW. The method also includes generating a bias across a substrate support in a lower portion of the processing region, where the bias is generated from a power source having a power of about 0.8 kW to about 2 kW. The method further includes exposing the amorphous carbon to atomic oxygen ions produced from the oxygen gas and the ion coupled plasma and removing the amorphous carbon from the interior surfaces by reacting the amorphous carbon with the atomic oxygen ions during a cleaning process, where the amorphous carbon is removed from the interior surfaces at a rate of about 0.1 μm/min to about 2.5 μm/min.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 depicts a schematic side cross-sectional view of an illustrative processing chamber, according to one or more embodiments described and discussed herein.

FIG. 2 is a flow chart of a method for cleaning the interior of a processing chamber, according to one or more embodiments described and discussed herein.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to clean methods for processing chambers, and more specifically relate to plasma clean methods for removing carbon films from surfaces within the processing chamber. The carbon films can be or include carbon, amorphous carbon, diamond-like carbon (DLC), or other carbon-containing inorganic materials. In one or more examples, a method for cleaning includes introducing a cleaning gas into a processing region within a processing chamber, where interior surfaces of the processing chamber have a coating containing amorphous carbon. The cleaning gas contains oxygen gas (O₂) and one or more other process gases, such as one or more noble gases. The method also includes generating an ion coupled plasma (ICP) from the cleaning gas within an upper portion of the processing region and generating a bias across a substrate support in a lower portion of the processing region. The method further includes exposing the amorphous carbon to atomic oxygen ions produced from the oxygen gas and the ICP and removing the amorphous carbon from the interior surfaces with the atomic oxygen ions during a cleaning process.

Embodiments relate to methods for cleaning plasma-enhanced chemical vapor deposition (PE-CVD) and plasma-enhanced atomic layer deposition (PE-ALD) processing chambers which are utilized to process substrates in the manufacture of electronic devices. Substrate processing includes deposition processes, etch processes, as well as other low pressure processes, plasma processes, and/or thermal processes used to manufacture electronic devices on substrates. Substrate processing also includes processes for cleaning substrates and/or the environments around the substrate. Examples of processing chambers and/or systems that may be adapted to benefit from exemplary aspects of the disclosure is the Producer® APF™ PE-CVD system commercially available from Applied Materials, Inc., located in Santa Clara, Calif. It is contemplated that other processing chambers, processing systems, and/or processing platforms, including those from other manufacturers, may be adapted to benefit from aspects of the cleaning methods described and discussed herein.

Embodiments of the methods and related processing equipment (e.g., chambers, systems, platforms) disclosed herein may be utilized for the fabrication of memory devices, and in particular, for the deposition of hardmasks utilized during fabrication of memory devices. Current memory devices are able to retain stored data for a very long period of time without applying a voltage thereto, and the reading rate of such memory devices is relatively high. It is relatively easy to erase stored data and rewrite data into the memory devices. Thus, memory devices have been widely used in micro-computers, automatic control systems, and the like. To increase the bit density and reduce the cost per bit of memory devices, 3D NAND (three-dimensional NOT AND) memory devices have been developed. Other memory devices, such as DRAM (dynamic random access memory), EM (expanded memory) and ReRAM (resistive random access memory), as well as advanced hardmask materials for forming the same, are also being developed to further facilitate advances in the semiconductor industry.

Vertical gate 3D memory cells are being explored for 3D NAND technologies to reduce cost as the number of memory cell layers increase. Oxide/silicon and oxide/nitride layer stacks are useful due to material integration advantages, but with an increasing number of memory cell layers, thickness of the layers becomes a limiting factor. Thus, while there is an interest in reducing the thickness of the memory cell layers, issues of oxide quality (e.g., breakdown voltage), silicon resistivity, and high aspect ratio etching persist with the reduced layer thickness.

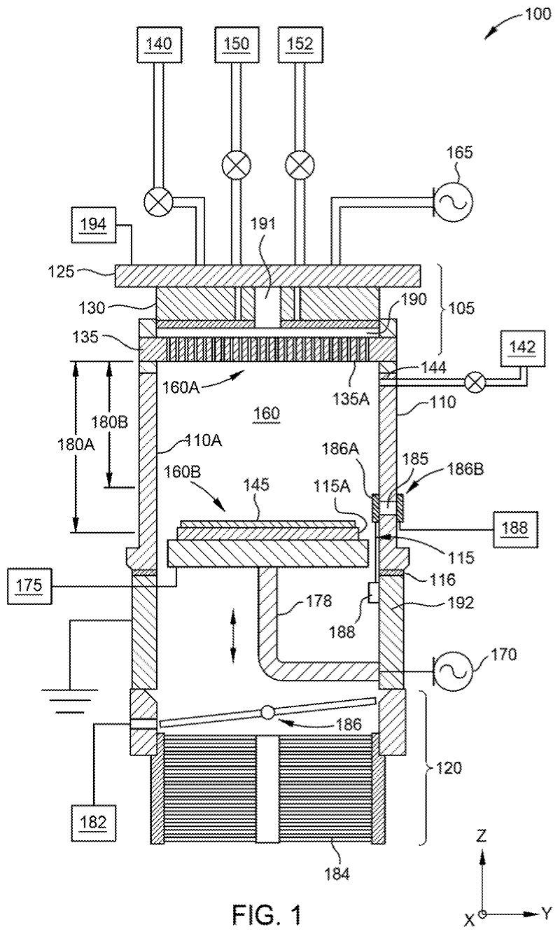

FIG. 1 is a schematic side cross-sectional view of an illustrative processing chamber 100 suitable for conducting a deposition process. In one or more embodiments, which can be combined with other embodiments described herein, the processing chamber 100 may be configured to deposit advanced patterning films onto a substrate, such as hardmask films, for example amorphous carbon hardmask films.

The processing chamber 100 includes a lid assembly 105, a spacer 110 disposed on a chamber body 192, a substrate support 115, and a variable pressure system 120. The lid assembly 105 includes a lid plate 125 and a heat exchanger 130. In the embodiment shown, which can be combined with other embodiments described herein, the lid assembly 105 also includes a showerhead 135. However, in other embodiments, which can be combined with other embodiments described herein, the lid assembly 105 includes a concave or dome-shaped gas introduction plate.

The lid assembly 105 is coupled to a first processing gas source 140. The first processing gas source 140 contains precursor gases for forming films on a substrate 145 supported on the substrate support 115. For example, the first processing gas source 140 includes one or more precursor gases, reactant gases, carrier gases, or other gases. In some examples, the first processing gas source 140 includes carbon-containing gases (e.g., acetylene), hydrogen-containing gases (e.g., H₂), dinitrogen gas (N₂), one or more noble gases (e.g., argon, helium, neon) among others.

The first processing gas source 140 provides process or precursor gases to a plenum 190 disposed in the lid assembly 105. The lid assembly 105 includes one or more channels for directing process gases from the first processing gas source 140 into the plenum 190. From the plenum, the process gas flows through the showerhead 135 into a processing volume or region 160. In some embodiments, which can be combined with other embodiments described herein, a second processing gas source 142 is fluidly coupled to the processing region 160 via an inlet 144 disposed through the spacer 110. As an example, the second processing gas source 142 includes process or precursor gases such as carbon-containing gases (e.g., acetylene), hydrogen-containing gases (e.g., H₂), dinitrogen gas (N₂), one or more noble gases (e.g., argon, helium, neon) among others. In one some embodiment, which can be combined with other embodiments described herein, a total flow rate of process gases into the processing region 160 is about 100 sccm to about 2,000 sccm. The flow of process gases in the processing region 160 via the second processing gas source 142 modulates the flow of process gases flow through the showerhead 135 such that the process gases are uniformly distributed in the processing region 160. In one or more examples, a plurality of inlets 144 may be radially distributed about the spacer 110. In such an example, gas flow to each of the inlets 144 may be separately controlled to further facilitate gas uniformity within the processing region 160.

In one or more embodiments, the lid assembly 105 is coupled to a third processing gas source 150 and a fourth processing gas source 152. The third processing gas source 150 and/or the fourth processing gas source 152 can be or include one or more cleaning gases, which are used to clean or otherwise remove contaminants (e.g., carbon) from the substrate 145, the substrate support 115, one or more interior surfaces (surfaces 110A, 115A, 135A, and/or others) of the processing chamber 100, such as within the processing region 160. There are a plurality of interior surfaces of the processing chamber 100, such as within the processing region 160 having an upper portion 160A and lower portion 160B. For example, the interior surfaces of the processing chamber 100 can be or include one or more surfaces 110A of the spacer 110, one or more surfaces 115A of the substrate support 115, one or more surfaces 135A of the showerhead 135, and/or one or more other surfaces.

The lid assembly 105 is coupled to a first or upper radio frequency (RF) power source 165. The first RF power source 165 facilitates maintenance or generation of plasma, such as a plasma generated from a cleaning gas. In one or more examples, the cleaning gas is ionized into a plasma in situ via the first RF power source 165. The substrate support 115 is coupled to a second or lower RF power source 170. The first RF power source 165 may be a high frequency RF power source (for example, about 13.56 MHz to about 120 MHz) and the second RF power source 170 may be a low frequency RF power source (for example, about 2 MHz to about 13.56 MHz). It is to be noted that other frequencies are also contemplated. In some implementations, the second RF power source 170 is a mixed frequency RF power source, providing both high frequency and low frequency power. Utilization of a dual frequency RF power source, particularly for the second RF power source 170, improves film deposition. In one or more examples, utilizing a second RF power source 170 provides dual frequency powers. A first frequency of about 2 MHz to about 13.56 MHz improves implantation of species into the deposited film, while a second frequency of about 13.56 MHz to about 120 MHz increases ionization and deposition rate of the film.

One or both of the first RF power source 165 and the second RF power source 170 are utilized in creating or maintaining a plasma in the processing region 160. For example, the second RF power source 170 may be utilized during a deposition process and the first RF power source 165 may be utilized during a cleaning process. In some deposition processes, the first RF power source 165 is used in conjunction with the second RF power source 170. During a deposition or etch process, one or both of the first RF power source 165 and the second RF power source 170 provide a power of about 100 watts to about 20,000 watts in the processing region 160 to facilitation ionization of a precursor gas. In one or more embodiments, which can be combined with other embodiments described herein, at least one of the first RF power source 165 and the second RF power source 170 are pulsed. In another embodiment, which can be combined with other embodiments described herein, the precursor gas includes helium and C₂H₂. In one or more embodiments, which can be combined with other embodiments described herein, C₂H₂ is provided at a flow rate of about 10 sccm to about 1,000 sccm and He is provided at a flow rate of about 50 sccm to about 10,000 sccm.

The substrate support 115 is coupled to an actuator 175 that provides movement thereof in the Z direction. The substrate support 115 is also coupled to an electrode or facilities cable 178 that allows vertical movement of the substrate support 115 while maintaining communication with the second RF power source 170 as well as other power and fluid connections. The spacer 110 is disposed on the chamber body 192. A height of the spacer 110 allows movement of the substrate support 115 vertically within the processing region 160. The height of the spacer 110 is about 0.5 inches to about 20 inches. In one or more examples, the substrate support 115 is movable from a first distance 180A to a second distance 180B relative to the lid assembly 105 (for example, relative to a lower surface of the showerhead 135). In another example, substrate support 115 is fixed at one of the first distance 180A and the second distance 180B. In contrast to conventional plasma enhanced chemical vapor deposition (PE-CVD) processes, the spacer 110 greatly increases the distance between (and thus the volume between) the substrate support 115 and the lid assembly 105. The increased distance between the substrate support 115 and the lid assembly 105 reduces collisions of ionized species in the volume process volume 160, resulting in deposition of film with less neutral stress, such as less than 2.5 gigapascal (GPa). Films deposited with less neutral stress facilitate improved planarity (e.g., less bowing) of substrates upon which the film is formed. Reduced bowing of substrates results in improved precision of downstream patterning operations.

The variable pressure system 120 includes a first pump 182 and a second pump 184. The first pump 182 is a roughing pump that may be utilized during a cleaning process and/or substrate transfer process. A roughing pump is generally configured for moving higher volumetric flow rates and/or operating a relatively higher (though still sub-atmospheric) pressure. In one or more examples, the first pump 182 maintains a pressure within the processing chamber less than 50 mTorr during a clean process. In another example, the first pump 182 maintains a pressure within the processing chamber of about 0.5 mTorr to about 10 Torr. Utilization of a roughing pump during clean operations facilitates relatively higher pressures and/or volumetric flow of cleaning gas (as compared to a deposition operation). The relatively higher pressure and/or volumetric flow during the cleaning operation improves cleaning of chamber surfaces.

The second pump 184 may be one a turbo pump and a cryogenic pump. The second pump 184 is utilized during a deposition process. The second pump 184 is generally configured to operate a relatively lower volumetric flow rate and/or pressure. For example, the second pump 184 is configured to maintain the processing region 160 of the processing chamber 100 at a pressure of less than about 50 mTorr. In another example, the second pump 184 maintains a pressure within the processing chamber 100 of about 0.5 mTorr to about 10 Torr. The reduced pressure of the processing region 160 maintained during deposition facilitates deposition of a film having reduced neutral stress and/or increased sp²-sp³ conversion, when depositing carbon-based hardmasks. Thus, the processing chamber 100 is configured to utilize both relatively lower pressure to improve deposition and relatively higher pressure to improve cleaning.

In some embodiments, which can be combined with other embodiments described herein, both of the first pump 182 and the second pump 184 are utilized during a deposition process to maintain the processing region 160 of the process chamber at a pressure of less than about 50 mTorr. In other embodiments, the first pump 182 and the second pump 184 maintain the processing region 160 at a pressure of about 0.5 mTorr to about 10 Torr. A valve 186 is utilized to control the conductance path to one or both of the first pump 182 and the second pump 184. The valve 186 also provides symmetrical pumping from the processing region 160.

The processing chamber 100 also includes a substrate transfer port 185. The substrate transfer port 185 is selectively sealed by an interior door 186A and an exterior door 186B. Each of the doors 186A and 186B are coupled to actuators 188. The doors 186A and 186B facilitate vacuum sealing of the processing region 160. The doors 186A and 186B also provide symmetrical RF application and/or plasma symmetry within the processing region 160. In one or more examples, at least the door 186A is formed of a material that facilitates conductance of RF power, such as stainless steel, aluminum, or alloys thereof. Seals 116, such as O-rings, disposed at the interface of the spacer 110 and the chamber body 192 may further seal the processing region 160. A controller 194 coupled to the processing chamber 100 is configured to control aspects of the processing chamber 100 during processing.

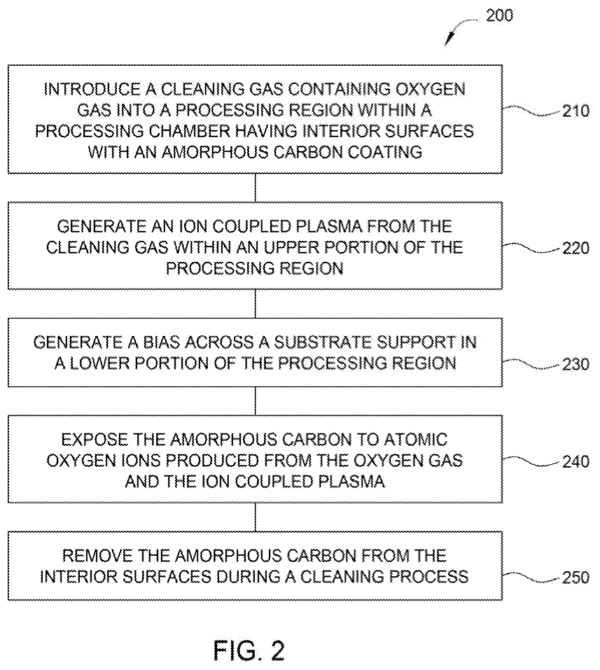

FIG. 2 is a flow chart of a method 200 for cleaning the interior of a processing chamber, according to one or more embodiments described and discussed herein. The method 200 includes multiple operations, such as operations 210-250 further described below. The method 200 is a cleaning process which can be used to clean processing chambers, such as the processing chamber 100 described and discussed herein, as well as many other types of processing chambers which have accumulated coatings, particulates, debris, and/or other contaminants. In some examples, the coatings, particulates, debris, and/or other contaminants can independently be or include carbon, amorphous carbon, diamond-like carbon (DLC), or other carbon-containing inorganic materials.

The amorphous carbon on the interior surfaces of the processing chamber or other surfaces within the processing region can have a thickness of about 0.1 μm, about 0.2 μm, about 0.3 μm, about 0.5 μm, about 0.7 μm to about 0.8 μm, about 1 μm, about 1.2 μm, about 1.4 μm, about 1.5 μm, about 1.8 μm, about 2 μm, about 2.2 μm, about 2.5 μm, or thicker. For example, the amorphous carbon on the interior surfaces of the processing chamber or other surfaces within the processing region can have a thickness of about 0.1 μm to about 2.5 μm, about 0.1 μm to about 2 μm, about 0.1 μm to about 1.8 μm, about 0.1 μm to about 1.5 μm, about 0.1 μm to about 1.2 μm, about 0.1 μm to about 1 μm, about 0.1 μm to about 0.8 μm, about 0.1 μm to about 0.5 μm, about 0.5 μm to about 2.5 μm, about 0.5 μm to about 2 μm, about 0.5 μm to about 1.8 μm, about 0.5 μm to about 1.5 μm, about 0.5 μm to about 1.2 μm, about 0.5 μm to about 1 μm, about 0.5 μm to about 0.8 μm, about 1 μm to about 2.5 μm, about 1 μm to about 2 μm, about 1 μm to about 1.8 μm, about 1 μm to about 1.5 μm, or about 1 μm to about 1.2 μm.

At operation 210, one or more cleaning gases are flowed or otherwise introduced into the processing region 160 within the processing chamber 100. The interior surfaces, including surfaces 110A, 115A, 135A, and/or other surfaces, have one or more coatings or other contaminants containing amorphous carbon disposed thereon. The cleaning gas can be or contain oxygen gas (O₂) and one or more noble gases (e.g., argon, helium, neon, or combinations thereof), nitrogen (N₂), or combinations thereof. Oxygen gas (O₂) and the noble gas (e.g., argon) can be flowed or otherwise introduced into the processing chamber separately or together as a mixture to produce the cleaning gas. For example, the cleaning gas is flowed or otherwise introduced into the processing chamber by flowing the oxygen gas and the noble gas therein.

The oxygen gas can be introduced into the processing chamber at a flow rate of about 100 sccm, about 200 sccm, about 300 sccm, about 500 sccm, about 700 sccm, or about 800 sccm to about 900 sccm, about 1,000 sccm, about 1,100 sccm, about 1,250 sccm, about 1,500 sccm, about 1,800 sccm, about 2,000 sccm, about 2,500 sccm, about 3,000 sccm, about 4,000 sccm, about 5,000 sccm, or greater. For example, the oxygen gas can be introduced into the processing chamber at a flow rate of about 100 sccm to about 5,000 sccm, about 100 sccm to about 3,000 sccm, about 200 sccm to about 3,000 sccm, about 200 sccm to about 2,000 sccm, about 200 sccm to about 1,000 sccm, about 200 sccm to about 500 sccm, about 500 sccm to about 3,000 sccm, about 500 sccm to about 2,000 sccm, about 500 sccm to about 1,500 sccm, about 500 sccm to about 1,100 sccm, about 500 sccm to about 1,000 sccm, about 500 sccm to about 800 sccm, about 700 sccm to about 3,000 sccm, about 700 sccm to about 2,000 sccm, about 700 sccm to about 1,500 sccm, about 700 sccm to about 1,100 sccm, about 700 sccm to about 1,000 sccm, or about 700 sccm to about 800 sccm.

The noble gas or other process gas can be introduced into the processing chamber at a flow rate of about 10 sccm, about 20 sccm, about 30 sccm, about 50 sccm, about 70 sccm, or about 80 sccm to about 90 sccm, about 100 sccm, about 110 sccm, about 125 sccm, about 150 sccm, about 180 sccm, about 200 sccm, about 250 sccm, about 300 sccm, about 400 sccm, about 500 sccm, or greater. For example, the noble gas or other process gas can be introduced into the processing chamber at a flow rate of about 10 sccm to about 500 sccm, about 10 sccm to about 300 sccm, about 20 sccm to about 300 sccm, about 20 sccm to about 200 sccm, about 20 sccm to about 100 sccm, about 20 sccm to about 50 sccm, about 50 sccm to about 300 sccm, about 50 sccm to about 200 sccm, about 50 sccm to about 150 sccm, about 50 sccm to about 110 sccm, about 50 sccm to about 100 sccm, about 50 sccm to about 80 sccm, about 80 sccm to about 300 sccm, about 80 sccm to about 200 sccm, about 80 sccm to about 150 sccm, about 80 sccm to about 120 sccm, or about 80 sccm to about 100 sccm.

In one or more examples, the oxygen gas has at a flow rate of about 200 sccm to about 3,000 sccm and the noble gas has at a flow rate of about 20 sccm to about 300 sccm when introduced in the processing chamber. In other examples, the oxygen gas has at a flow rate of about 500 sccm to about 1,500 sccm and the noble gas at a flow rate of about 50 sccm to about 150 sccm when introduced in the processing chamber. In some examples, the oxygen gas has at a flow rate of about 700 sccm to about 1,100 sccm and the noble gas at a flow rate of about 80 sccm to about 120 sccm when introduced in the processing chamber.

In one or more embodiments, the cleaning gas contains about 70 mole percent (mol %), about 72 mol %, about 75 mol %, about 78 mol %, about 80 mol %, about 82 mol %, about 85 mol %, or about 88 mol % to about 90 mol %, about 92 mol %, about 94 mol %, about 95 mol %, about 96 mol %, about 97 mol %, about 98 mol %, about 99 mol %, or about 99.5 mol % of oxygen gas. For example, the cleaning gas contains about 70 mol % to about 99 mol %, about 75 mol % to about 99 mol %, about 80 mol % to about 99 mol %, about 85 mol % to about 99 mol %, about 90 mol % to about 99 mol %, about 95 mol % to about 99 mol %, about 70 mol % to about 95 mol %, about 75 mol % to about 95 mol %, about 80 mol % to about 95 mol %, about 85 mol % to about 95 mol %, about 90 mol % to about 95 mol %, about 95 mol % to about 95 mol %, about 70 mol % to about 90 mol %, about 75 mol % to about 90 mol %, about 80 mol % to about 90 mol %, about 85 mol % to about 90 mol %, about 90 mol % to about 92 mol %, about 70 mol % to about 85 mol %, about 75 mol % to about 85 mol %, about 80 mol % to about 85 mol %, or about 85 mol % to about 88 mol % of oxygen gas.

The cleaning gas contains about 0.5 mol %, about 1 mol %, about 2 mol %, about 3 mol %, about 4 mol %, about 5 mol %, about 6 mol %, about 7 mol %, about 8 mol %, about 9 mol %, or about 10 mol % to about 11 mol %, about 12 mol %, about 14 mol %, about 15 mol %, about 16 mol %, about 18 mol %, about 20 mol %, about 22 mol %, about 25 mol %, or about 30 mol % one or more noble gases and/or other process gases. For example, the cleaning gas contains about 0.5 mol % to about 30 mol %, about 1 mol % to about 30 mol %, about 1 mol % to about 25 mol %, about 1 mol % to about 20 mol %, about 1 mol % to about 18 mol %, about 1 mol % to about 15 mol %, about 1 mol % to about 12 mol %, about 1 mol % to about 10 mol %, about 1 mol % to about 8 mol %, about 1 mol % to about 6 mol %, about 1 mol % to about 5 mol %, about 1 mol % to about 4 mol %, about 1 mol % to about 3 mol %, about 1 mol % to about 2 mol %, about 5 mol % to about 30 mol %, about 5 mol % to about 25 mol %, about 5 mol % to about 20 mol %, about 5 mol % to about 18 mol %, about 5 mol % to about 15 mol %, about 5 mol % to about 12 mol %, about 5 mol % to about 10 mol %, about 5 mol % to about 8 mol %, about 5 mol % to about 6 mol %, about 10 mol % to about 30 mol %, about 10 mol % to about 25 mol %, about 10 mol % to about 20 mol %, about 10 mol % to about 18 mol %, about 10 mol % to about 15 mol %, or about 10 mol % to about 12 mol % of one or more noble gases and/or other process gases.

In one or more examples, the cleaning gas contains about 75 mole percent (mol %) to about 99 mol % of oxygen gas (O₂) and about 1 mol % to about 20 mol % of one or more noble gases. In some examples, the cleaning gas contains about 80 mol % to about 95 mol % of oxygen gas and about 5 mol % to about 15 mol % of a noble gas. In other examples, the cleaning gas contains about 88 mol % to about 92 mol % of oxygen gas and about 8 mol % to about 12 mol % of a noble gas.

At operation 220, an ion coupled plasma (ICP) can be generated or otherwise produced from the cleaning gas within the upper portion 160A of the processing region 160 during the cleaning process. A potential from the first or upper RF power source 165 can be applied across an electrode within the upper portion 160A of the processing region 160 for generating the ion coupled plasma. In one or more examples, the electrode can be or include the lid assembly 105 and/or any parts or portions thereof, such as the lid plate 125, the heat exchanger 130, and/or the showerhead 135. The first RF power source 165 facilitates maintenance or generation of plasma within the processing region 160.

At operation 230, a bias can be generated or otherwise produced across the substrate support 115 in the lower portion 160B of the processing region 160 during the cleaning process. A potential from the second or lower RF power source 170 can be applied across an electrode and/or the facilities cable 178 within the lower portion 160B of the processing region 160 for generating the bias across the substrate support 115.

In one or more examples, each of the ion coupled plasma and the bias can independently generate from a power source having a power of about 0.5 kilowatts (kW), about 0.8 kW, about 1 kW, about 1.2 kW, about 1.5 kW, or about 1.8 kW to about 2 kW, about 2.5 kW, about 3 kW, about 4 kW, about 5 kW, about 6 kW, about 8 kW, about 10 kW, about 15 kW, or about 20 kW. For example, each of the ion coupled plasma and the bias can independently generate from a power source having a power of about 0.5 kW to about 10 kW, about 0.5 kW to about 8 kW, about 0.5 kW to about 6 kW, about 0.5 kW to about 5 kW, about 0.5 kW to about 4 kW, about 0.5 kW to about 3 kW, about 0.5 kW to about 2 kW, or about 0.5 kW to about 1 kW. In some examples, the ion coupled plasma is generated from a power source having a power of about 3 kW to about 5 kW, and the bias is generated from a power source having a power of about 0.8 kW to about 2 kW.

At operation 240, the amorphous carbon and/or other contaminant is exposed to atomic oxygen ions produced from the oxygen gas and the ion coupled plasma during the cleaning process. At operation 250, the amorphous carbon is removed from the interior surfaces by reacting the amorphous carbon with the atomic oxygen ions during the cleaning process. Operations 240 and 250 typically are occurring simultaneously—but can also occur at different phases. The processing region 160 can be maintained at a pressure of about 20 mTorr to about 200 mTorr during the cleaning process.

In one or more embodiments, the amorphous carbon and/or other contaminant is etched, oxidized, or otherwise removed from the interior surfaces of the processing chamber or other surfaces within the processing region at a rate of about 0.1 μm/min, about 0.2 μm/min, about 0.3 μm/min, about 0.5 μm/min, about 0.7 μm/min to about 0.8 μm/min, about 1 μm/min, about 1.2 μm/min, about 1.4 μm/min, about 1.5 μm/min, about 1.8 μm/min, about 2 μm/min, about 2.2 μm/min, about 2.5 μm/min, or faster. For example, the amorphous carbon and/or other contaminant on the interior surfaces of the processing chamber or other surfaces within the processing region can have a thickness of about 0.1 μm/min to about 2.5 μm/min, about 0.2 μm/min to about 2.5 μm/min, about 0.2 μm/min to about 2 μm/min, about 0.2 μm/min to about 1.8 μm/min, about 0.2 μm/min to about 1.5 μm/min, about 0.2 μm/min to about 1.2 μm/min, about 0.2 μm/min to about 1 μm/min, about 0.2 μm/min to about 0.8 μm/min, about 0.2 μm/min to about 0.5 μm/min, about 0.3 μm/min to about 2 μm/min, about 0.3 μm/min to about 1.5 μm/min, about 0.3 μm/min to about 1 μm/min, about 0.3 μm/min to about 0.8 μm/min, about 0.3 μm/min to about 0.5 μm/min, about 0.5 μm/min to about 2 μm/min, about 0.5 μm/min to about 1.8 μm/min, about 0.5 μm/min to about 1.5 μm/min, about 0.5 μm/min to about 1.2 μm/min, about 0.5 μm/min to about 1 μm/min, about 0.5 μm/min to about 0.8 μm/min, about 1 μm/min to about 2.5 μm/min, about 1 μm/min to about 2 μm/min, about 1 μm/min to about 1.8 μm/min, or about 1 μm/min to about 1.5 μm/min.

The cleaning process lasts for about 10 seconds, about 20 seconds, about 30 seconds, about 45 seconds, or about 60 seconds to about 1.5 minutes, about 2 minutes, about 2.5 minutes, about 3 minutes, about 4 minutes, about 5 minutes, about 6 minutes, about 8 minutes, about 10 minutes, or longer. For example, the cleaning process lasts for about 10 seconds to about 10 minutes, about 10 seconds to about 6 minutes, about 10 seconds to about 5 minutes, about 10 seconds to about 4 minutes, about 10 seconds to about 3 minutes, about 10 seconds to about 2 minutes, about 10 seconds to about 1.5 minutes, about 10 seconds to about 60 seconds, about 10 seconds to about 45 seconds, about 10 seconds to about 30 seconds, about 10 seconds to about 20 seconds, about 30 seconds to about 10 minutes, about 30 seconds to about 6 minutes, about 30 seconds to about 5 minutes, about 30 seconds to about 4 minutes, about 30 seconds to about 3 minutes, about 30 seconds to about 2 minutes, about 30 seconds to about 1.5 minutes, about 30 seconds to about 60 seconds, about 30 seconds to about 45 seconds, about 45 seconds to about 8 minutes, about 45 seconds to about 4 minutes, about 45 seconds to about 2 minutes, about 60 seconds to about 10 minutes, about 60 seconds to about 6 minutes, about 60 seconds to about 5 minutes, about 60 seconds to about 4 minutes, about 60 seconds to about 3 minutes, about 60 seconds to about 2 minutes, or about 60 seconds to about 1.5 minutes.

Embodiments of the present disclosure further relate to any one or more of the following paragraphs 1-21:

1. A method for cleaning a processing chamber, comprising: introducing a cleaning gas into a processing region within a processing chamber, wherein interior surfaces of the processing chamber have a coating comprising amorphous carbon, and wherein the cleaning gas comprises: about 75 mole percent (mol %) to about 99 mol % of oxygen gas (O₂), and about 1 mol % to about 20 mol % of a noble gas; generating an ion coupled plasma from the cleaning gas within an upper portion of the processing region; generating a bias across a substrate support in a lower portion of the processing region; exposing the amorphous carbon to atomic oxygen ions produced from the oxygen gas and the ion coupled plasma; and removing the amorphous carbon from the interior surfaces by reacting the amorphous carbon with the atomic oxygen ions during a cleaning process.

2. A method for cleaning a processing chamber, comprising: introducing a cleaning gas into a processing region within a processing chamber, wherein interior surfaces of the processing chamber have a coating comprising amorphous carbon, wherein the cleaning gas comprises oxygen gas (O₂) and a noble gas, and wherein the cleaning gas is introduced into the processing chamber by flowing: the oxygen gas at a flow rate of about 200 sccm to about 3,000 sccm, and the noble gas at a flow rate of about 20 sccm to about 300 sccm; generating an ion coupled plasma from the cleaning gas within an upper portion of the processing region; generating a bias across a substrate support in a lower portion of the processing region; exposing the amorphous carbon to atomic oxygen ions produced from the oxygen gas and the ion coupled plasma; and removing the amorphous carbon from the interior surfaces by reacting the amorphous carbon with the atomic oxygen ions during a cleaning process.

3. A method for cleaning a processing chamber, comprising: introducing a cleaning gas into a processing region within a processing chamber, wherein interior surfaces of the processing chamber have a coating comprising amorphous carbon, and wherein the cleaning gas comprises: about 75 mole percent (mol %) to about 99 mol % of oxygen gas (O₂), and about 1 mol % to about 20 mol % of argon; generating an ion coupled plasma from the cleaning gas within an upper portion of the processing region, wherein the ion coupled plasma is generated from a power source having a power of about 3 kW to about 5 kW; generating a bias across a substrate support in a lower portion of the processing region, wherein the bias is generated from a power source having a power of about 0.8 kW to about 2 kW; exposing the amorphous carbon to atomic oxygen ions produced from the oxygen gas and the ion coupled plasma; and removing the amorphous carbon from the interior surfaces by reacting the amorphous carbon with the atomic oxygen ions during a cleaning process, wherein the amorphous carbon is removed from the interior surfaces at a rate of about 0.1 μm/min to about 2.5 μm/min.

4. The method according to any one of paragraphs 1-3, wherein the amorphous carbon is removed from the interior surfaces at a rate of about 0.1 μm/min to about 2.5 μm/min.

5. The method according to any one of paragraphs 1-4, wherein the amorphous carbon is removed from the interior surfaces at a rate of about 0.2 μm/min to about 2 μm/min.

6. The method according to any one of paragraphs 1-5, wherein the amorphous carbon is removed from the interior surfaces at a rate of about 0.3 μm/min to about 1.5 μm/min.

7. The method according to any one of paragraphs 1-6, wherein the amorphous carbon on the interior surfaces has a thickness of about 0.5 μm to about 2 μm.

8. The method according to any one of paragraphs 1-7, wherein the cleaning gas comprises: about 80 mol % to about 95 mol % of oxygen gas, and about 5 mol % to about 15 mol % of the noble gas.

9. The method according to any one of paragraphs 1-8, wherein the noble gas comprises argon, and wherein the cleaning gas comprises: about 88 mol % to about 92 mol % of oxygen gas, and about 8 mol % to about 12 mol % of the noble gas.

10. The method according to any one of paragraphs 1-9, wherein the cleaning gas is introduced into the processing chamber by flowing: the oxygen gas at a flow rate of about 200 sccm to about 3,000 sccm, and the noble gas at a flow rate of about 20 sccm to about 300 sccm.

11. The method according to any one of paragraphs 1-10, wherein the cleaning gas is introduced into the processing chamber by flowing: the oxygen gas at a flow rate of about 500 sccm to about 1,500 sccm, and the noble gas at a flow rate of about 50 sccm to about 150 sccm.

12. The method according to any one of paragraphs 1-11, further comprising maintaining the processing region at a pressure of about 20 mTorr to about 200 mTorr during the cleaning process.

13. The method according to any one of paragraphs 1-12, further comprising applying a potential across an electrode within the upper portion of the processing region for generating the ion coupled plasma.

14. The method according to any one of paragraphs 1-13, further comprising applying a potential across an electrode within the lower portion of the processing region for generating the bias across the substrate support.

15. The method according to any one of paragraphs 1-14, wherein the ion coupled plasma and the bias are each independently generated from a power source having a power of about 0.5 kW to about 10 kW.

16. The method according to any one of paragraphs 1-15, wherein the ion coupled plasma and the bias are each independently generated from a power source having a power of about 0.5 kW to about 6 kW.

17. The method according to any one of paragraphs 1-16, wherein the ion coupled plasma is generated from a power source having a power of about 3 kW to about 5 kW.

18. The method according to any one of paragraphs 1-17, wherein the bias is generated from a power source having a power of about 0.8 kW to about 2 kW.

19. The method according to any one of paragraphs 1-18, wherein the cleaning process lasts for about 30 seconds to about 6 minutes.

20. The method according to any one of paragraphs 1-19, wherein the cleaning process lasts for about 30 seconds to about 3 minutes.

21. The method according to any one of paragraphs 1-20, wherein the cleaning process lasts for about 45 seconds to about 2 minutes.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising”, it is understood that we also contemplate the same composition or group of elements with transitional phrases “consisting essentially of,” “consisting of”, “selected from the group of consisting of,” or “is” preceding the recitation of the composition, element, or elements and vice versa.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

1. A method for cleaning a processing chamber, comprising:
introducing a cleaning gas into a processing region within a processing chamber, wherein interior surfaces of the processing chamber have a coating comprising amorphous carbon, and wherein the cleaning gas comprises:
about 75 mole percent (mol %) to about 99 mol % of oxygen gas (O₂), and
about 1 mol % to about 20 mol % of a noble gas;
generating an ion coupled plasma from the cleaning gas within an upper portion of the processing region;
generating a bias across a substrate support in a lower portion of the processing region;
exposing the amorphous carbon to atomic oxygen ions produced from the oxygen gas and the ion coupled plasma; and
removing the amorphous carbon from the interior surfaces by reacting the amorphous carbon with the atomic oxygen ions during a cleaning process.

2. The method of claim 1, wherein the amorphous carbon is removed from the interior surfaces at a rate of about 0.1 μm/min to about 2.5 μm/min.

3. The method of claim 1, wherein the amorphous carbon on the interior surfaces has a thickness of about 0.5 μm to about 2 μm.

4. The method of claim 1, wherein the noble gas comprises argon, and wherein the cleaning gas comprises:
about 88 mol % to about 92 mol % of oxygen gas, and
about 8 mol % to about 12 mol % of the noble gas.

5. The method of claim 1, wherein the cleaning gas is introduced into the processing chamber by flowing:
the oxygen gas at a flow rate of about 200 sccm to about 3,000 sccm, and
the noble gas at a flow rate of about 20 sccm to about 300 sccm.

6. The method of claim 1, wherein the cleaning gas is introduced into the processing chamber by flowing:
the oxygen gas at a flow rate of about 500 sccm to about 1,500 sccm, and
the noble gas at a flow rate of about 50 sccm to about 150 sccm.

7. The method of claim 1, further comprising maintaining the processing region at a pressure of about 20 mTorr to about 200 mTorr during the cleaning process.

8. The method of claim 1, further comprising applying a potential across an electrode within the upper portion of the processing region for generating the ion coupled plasma.

9. The method of claim 1, further comprising applying a potential across an electrode within the lower portion of the processing region for generating the bias across the substrate support.

10. The method of claim 1, wherein the ion coupled plasma and the bias are each independently generated from a power source having a power of about 0.5 kW to about 6 kW.

11. The method of claim 10, wherein the ion coupled plasma is generated from a power source having a power of about 3 kW to about 5 kW.

12. The method of claim 10, wherein the bias is generated from a power source having a power of about 0.8 kW to about 2 kW.

13. The method of claim 1, wherein the cleaning process lasts for about 30 seconds to about 6 minutes.

14. A method for cleaning a processing chamber, comprising:
introducing a cleaning gas into a processing region within a processing chamber, wherein interior surfaces of the processing chamber have a coating comprising amorphous carbon, wherein the cleaning gas comprises oxygen gas (O₂) and a noble gas, and wherein the cleaning gas is introduced into the processing chamber by flowing:
the oxygen gas at a flow rate of about 200 sccm to about 3,000 sccm, and
the noble gas at a flow rate of about 20 sccm to about 300 sccm;
generating an ion coupled plasma from the cleaning gas within an upper portion of the processing region;
generating a bias across a substrate support in a lower portion of the processing region;
exposing the amorphous carbon to atomic oxygen ions produced from the oxygen gas and the ion coupled plasma; and
removing the amorphous carbon from the interior surfaces by reacting the amorphous carbon with the atomic oxygen ions during a cleaning process.

15. The method of claim 14, wherein the amorphous carbon is removed from the interior surfaces at a rate of about 0.1 μm/min to about 2.5 μm/min.

16. The method of claim 14, wherein the cleaning gas comprises:
about 80 mole percent (mol %) to about 95 mol % of oxygen gas, and
about 5 mol % to about 15 mol % of the noble gas.

17. The method of claim 14, wherein the cleaning gas is introduced into the processing chamber by flowing:
the oxygen gas at a flow rate of about 500 sccm to about 1,500 sccm, and
the noble gas at a flow rate of about 50 sccm to about 150 sccm.

18. The method of claim 14, wherein the ion coupled plasma is generated from a power source having a power of about 3 kW to about 5 kW, and wherein the bias is generated from a power source having a power of about 0.8 kW to about 2 kW.

19. The method of claim 14, wherein the cleaning process lasts for about 30 seconds to about 6 minutes.

20. A method for cleaning a processing chamber, comprising:
introducing a cleaning gas into a processing region within a processing chamber, wherein interior surfaces of the processing chamber have a coating comprising amorphous carbon, and wherein the cleaning gas comprises:
about 75 mole percent (mol %) to about 99 mol % of oxygen gas (O₂), and
about 1 mol % to about 20 mol % of argon;
generating an ion coupled plasma from the cleaning gas within an upper portion of the processing region, wherein the ion coupled plasma is generated from a power source having a power of about 3 kW to about 5 kW;
generating a bias across a substrate support in a lower portion of the processing region, wherein the bias is generated from a power source having a power of about 0.8 kW to about 2 kW;
exposing the amorphous carbon to atomic oxygen ions produced from the oxygen gas and the ion coupled plasma; and
removing the amorphous carbon from the interior surfaces by reacting the amorphous carbon with the atomic oxygen ions during a cleaning process, wherein the amorphous carbon is removed from the interior surfaces at a rate of about 0.1 μm/min to about 2.5 μm/min.
